(19) United States
(12) Patent Application Publication
(10) Pub. No.: US 2026/0002984 A1
(43) Pub. Date: Jan. 1, 2026

(54) APPARATUS AND METHOD FOR TESTING A SEMICONDUCTOR PACKAGE

(71) Applicant: JCET STATS ChipPAC Korea Limited, Incheon (KR)

(72) Inventors: JuNo LIM, Gyeonggi-do (KR); WonJae LEE, Incheon (KR); SeungJun BAEK, Incheon (KR)

(21) Appl. No.: 19/248,407

(22) Filed: Jun. 24, 2025

(30) Foreign Application Priority Data
Jun. 26, 2024 (CN) 202410839913.6

(51) Int. Cl. G01R 31/28

(52) U.S. Cl. CPC G01R 31/2863; G01R 31/2896

(57) ABSTRACT

A apparatus for testing a semiconductor package comprises: a test board; a reference module disposed on the test board, wherein the reference module has a base substrate with a set of test pads and at least one reference electronic component mounted on the base substrate, the at least one reference electronic component has a same composition and layout as the at least one electronic component of the semiconductor package; and a test socket disposed on the test board, wherein the test socket comprises: a socket body for accommodating the reference module and the semiconductor package; and contact pins vertically extending through the socket body to set up an electrical connection between the set of conductive pads of the semiconductor component and the set of test pads of the reference module.

### TECHNICAL FIELD

The present application generally relates to semiconductor technology, and more particularly, to an apparatus for testing a semiconductor package and a method for testing a semiconductor package.

### BACKGROUND OF THE INVENTION

The semiconductor industry is constantly faced with complex integration challenges as consumers want their electronics to be smaller, faster and higher performance with more and more functionalities packed into a single device. Semiconductor packages that have undergone complicated processing are subjected to various types of electrical tests so as to test their characteristics and for defects thereof.

To this end, a test socket is used to electrically connect metallic wires or contact pads of a test board (for example, a printed circuit board) mounted in test equipment and external terminals of a semiconductor package to be tested. That is, when a semiconductor package is being tested, the test socket serves as an interface to electrically connect the test board of the test equipment and the semiconductor package under test.

Therefore, a need exists for a highly convenient and cost-saving apparatus for testing a semiconductor package.

### SUMMARY OF THE INVENTION

An objective of the present application is to provide a highly convenient and cost-saving apparatus for testing a semiconductor package.

According to an aspect of the present application, an apparatus for testing a semiconductor package is provided, wherein the semiconductor package comprises a semiconductor component, at least one electronic component and a mold cap encapsulating the semiconductor component and the at least one electronic component, the semiconductor component has a set of conductive pads exposed from the mold cap, and wherein the apparatus comprises: a test board; a reference module disposed on the test board, wherein the reference module has a base substrate with a set of test pads and at least one reference electronic component mounted on the base substrate, the at least one reference electronic component has a same composition and layout as the at least one electronic component of the semiconductor package; and a test socket disposed on the test board, wherein the test socket comprises: a socket body having an upper seat for seating the semiconductor package and a lower cavity below the upper seat and for accommodating the reference module, such that the set of test pads of the reference module are vertically aligned with the set of conductive pads of the semiconductor component when the semiconductor package is seated in the upper seat; and contact pins vertically extending through the socket body between the upper seat and the lower cavity and movable vertically relative to the socket body, wherein when the semiconductor package is under test, the contact pins are pressed by the semiconductor package against the reference module to set up an electrical connection between the set of conductive pads of the semiconductor component and the set of test pads of the reference module.

In another aspect of the present application, a method for testing a semiconductor package is provided, wherein the semiconductor package comprises a semiconductor component, at least one electronic component and a mold cap encapsulating the semiconductor component and the at least one electronic component, the semiconductor component has a set of conductive pads exposed from the mold cap; and wherein the method comprises: providing a reference module disposed on the test board, wherein the reference module has a base substrate with a set of test pads and at least one reference electronic component mounted on the base substrate, the at least one reference electronic component has a same composition and layout as the at least one electronic component of the semiconductor package; placing the reference module on a test board; placing a test socket on the test board, wherein the test socket comprises a socket body having an upper seat and a lower cavity below the upper seat, and contact pins vertically extending through the socket body between the upper seat and the lower cavity and movable relative to the socket body, and wherein the reference module is accommodated within the lower cavity; placing the semiconductor package in the upper seat of the test socket; and pressing the semiconductor package toward the test board to press the contact pins against the reference module to set up an electrical connection between the set of conductive pads of the semiconductor component and the set of test pads of the reference module.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E illustrate an apparatus for testing a semiconductor package according to a first embodiment of the present application.

FIGS. 2A to 2G illustrate various steps of a method for testing a semiconductor package according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a test socket serves as an interface to electrically connect a test board of a test equipment and a semiconductor package under test when the semiconductor package is being tested. To be more specific, the test socket may include connect components which set up an electrical connection between conductive pads of the semiconductor package under test and the test board. However, it is difficult to test electronic components packed within the semiconductor package since conductive pads of respective electronic components to be tested are encapsulated within mold caps. Moreover, removing mold caps to expose the conductive pads of the electronic components to be tested may also cause damage to the electronic components, which is undesirable. Other conventional methods may require additional adjustments to an existing configuration of the test equipment, which causes inconvenience and additional cost.

To address this issue, an apparatus for testing a semiconductor package is provided. The semiconductor package includes a semiconductor component to be tested, at least one electronic component and a mold cap encapsulating them. The apparatus includes a test board, a reference module disposed on a test board of the apparatus and a test socket. In particular, the reference module has a base substrate and at least one reference electronic component mounted thereon, and the at least one reference electronic component has a same composition and layout as the at least one electronic component of the semiconductor package. When testing the semiconductor package, a test socket may set up an electrical connection between conductive pads of the semiconductor component exposed from the mold cap and test pads of the base substrate of the reference module via contact pins. Therefore, the apparatus creates a complete electronic module including the semiconductor component to be tested and the at least one reference electronic component to mimic the semiconductor package including the semiconductor component and the at least one electronic component without damaging a structure of the semiconductor package, which brings convenience and saves cost when testing the semiconductor package.

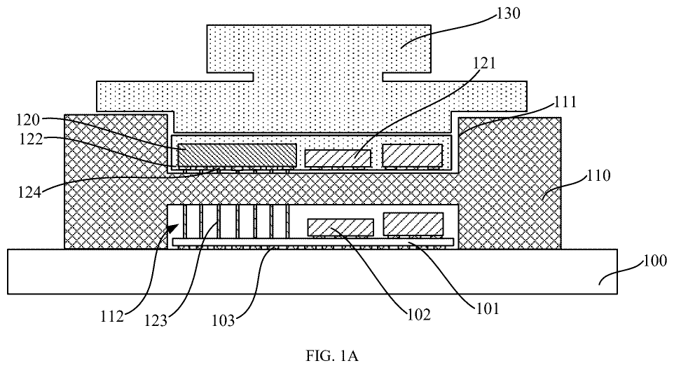

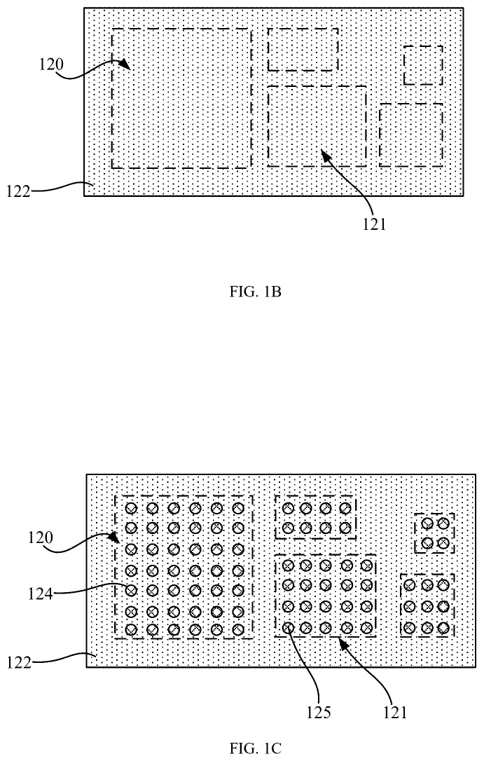

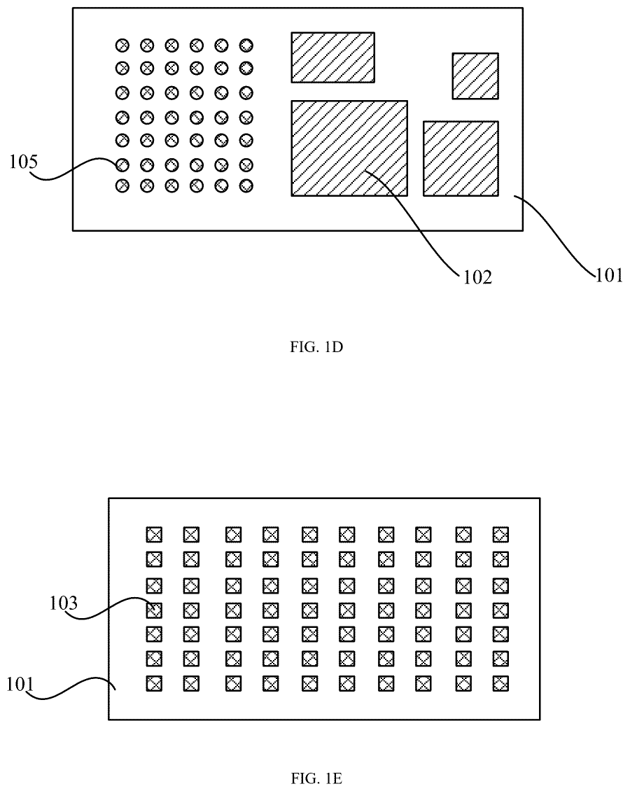

FIGS. 1A to 1E illustrate an apparatus for testing a semiconductor package according to a first embodiment of the present application.

In particular, FIG. 1A illustrates a side view of the apparatus for testing a semiconductor package when the semiconductor package is under test. FIG. 1B illustrates a top view of the semiconductor package shown in FIG. 1A, FIG. 1C illustrates a bottom view of the semiconductor package shown in FIG. 1A, FIG. 1D illustrates a top view of a reference module shown in FIG. 1A and FIG. 1E illustrates a bottom view of the reference module shown in FIG. 1A.

As shown in FIGS. 1A to 1C, a semiconductor package is provided. The semiconductor package is to be tested to identify any defect of a component encapsulated within the semiconductor package, for example, a semiconductor component 120. In some embodiments, the semiconductor component 120 may include a semiconductor die. It can also be appreciated that the semiconductor component 120 may include various types of electronic modules, such as semiconductor chips, resistors, capacitors or other large-sized devices with complex functionality. The semiconductor package further includes at least one electronic component 121, and a mold cap 122 encapsulating the semiconductor component 120 and the at least one electronic component 121. The at least one electronic component 121 may or may not be a same type of module or component as the semiconductor component 120. Moreover, the semiconductor component 120 has a set of conductive pads 124 exposed from the mold cap 122 to provide an electrical connection between the semiconductor component 120 and external connection structures. Similarly, each of the at least one electronic component 121 has an additional set of conductive pads 125 exposed from the mold cap 122.

For the semiconductor package, the semiconductor component 120 and the at least one electronic component 121 may operate together as an integrated electronic system in practical applications. In some embodiments, a testing process may be carried out to particularly test the semiconductor component 120 encapsulated within the mold cap 122. That is, an effective operation of the semiconductor component 120 may be tested along with expected functionalities of other electronic component(s) 121 within the semiconductor package. In some embodiments, the semiconductor package may be pre-packaged on a package substrate, which may be removed to expose the conductive pads 124, 125 of the semiconductor component 120 and the at least one electronic component 121. In some other embodiments, the semiconductor package may be formed using a substrate-free fabrication process.

Still referring to FIG. 1A, the apparatus for testing the semiconductor package includes a test board 100, which serves as a base of the apparatus. The test board 100 may have a plurality of contact pads (not shown) on its front surface, which may be coupled with a signal generator via various connection means (not shown), for example, traces, plugs or redistribution structures (RDSs) within the test board 100. In some embodiments, the connection means may have a respective layout corresponding to a layout of the semiconductor package, for example, a specific length corresponding to a size of the semiconductor package. Moreover, the signal generator can generate various test signals and test patterns for testing the semiconductor package.

Furthermore, the apparatus includes a reference module mounted on the test board 100, which serves as an auxiliary unit when the semiconductor package is under test. Detailed structures of the reference module are illustrated in FIGS. 1A, 1D and 1E. To be more specific, the reference module includes a base substrate 101. In some embodiments, the reference module may have a same size or layout as that of the semiconductor package under test. The base substrate 101 has a set of test pads 105 on a front surface for providing an electrical connection between the reference module and external connection structures. The set of test pads 105 are exposed from the base substrate 101 without components formed thereon. It can be appreciated that the test pads 105 may be exposed portions of interconnect wires formed within the base substrate 101. The test pads 105 and the additional conductive pads 103 may be electrically connected with each other through the interconnect wires formed within the base substrate 101, for example. The test pads 105 of the base substrate 101 of the reference module are electrically coupled to the test board 100 via additional conductive pads 103 between the base substrate 101 and the test board 100. Furthermore, the reference module includes at least one reference electronic component 102 mounted on the base substrate 101 via solder bumps. The at least one reference electronic component 102 has a same composition, structure, functionality and layout as the at least one electronic component 121 of the semiconductor package.

Still referring to FIG. 1A, the apparatus includes a test socket disposed on the test board 100. The test socket may accommodate the semiconductor package and the reference module therewithin, and at the same time, provide an electrical connection between the semiconductor package and the reference module, so as to build a complete test environment or system to test the semiconductor component 120 within the semiconductor package.

The test socket includes a socket body 110 which is constructed to have a double-layer holder structure, with each layer configured to accommodate one of the semiconductor package and the reference module, respectively. To be more specific, the socket body 110 has an upper seat 111 defining an interior space, which serves as an upper layer structure for seating the semiconductor package, and a lower cavity 112 below the upper seat 111 as a lower layer structure for accommodating the reference module. An interior space defined by the upper seat 111 and the lower cavity 112 may have a same size or layout as the semiconductor package and the reference module, respectively. Also, the interior space defined by the upper seat 111 may overlap with the lower cavity 112. In some embodiments, the socket body 110 may include two vertical parts extending perpendicular to the test board 100 and parallel to each other, and a horizontal part or platform extending between the two vertical parts at a substantially middle level, which forms an “H” shape in a side view of the socket body 110. In this case, the semiconductor package may be disposed on the horizontal part.

When the semiconductor package is seated in the upper seat 111 and the reference module is accommodated within the lower cavity 112, the set of test pads 105 of the reference module are vertically aligned with the set of conductive pads 124 of the semiconductor component 120. The test socket further includes contact pins 123 vertically extending through the socket body 110 between the upper seat 111 and the lower cavity 112. In particular, each of the contact pins 123 electrically couples one of the test pads 105 of the reference module to a respective one of the conductive pads 124 of the semiconductor component 120, so as to set up an electrical connection between the semiconductor component 120 and the base substrate 101, and thus sets up an electrical connection between the semiconductor component 120 and the at least one reference electronic component 121. Since the reference module is electrically coupled to the test board 100 via additional conductive pads 103, effective signaling may be allowed between the semiconductor component 120, the at least one reference electronic component 121 and the test board 100 when the semiconductor component 120 is being tested. Preferably, the additional conductive pads 103 on the back surface of the base substrate 101 may have a similar or same pattern as that of the conductive pads 124, 125 of the semiconductor component 120 and the electronic component(s) 121 for better simulation purpose.

Furthermore, the socket body 110 may include slots extending therethrough each receiving one of the contact pins 123. The socket body 110 can fix and support the contact pins 123 to protect them from deformation and external physical impact, which improves an alignment accuracy between the set of test pads 105 and the set of conductive pads 124, respectively. In some embodiments, the slots may be distributed horizontally across almost all of the socket body 110 between the upper seat 111 and the lower cavity 112, which can receive the contact pins 123 with various arrangements relative to the socket body 110 when testing components with various layouts within the semiconductor package. In this case, before testing a specific component, the contact pins 123 can be inserted through a respective set of slots which are aligned with the conductive pads 124 of the component to be tested. As such, the socket body 110 can be reused when testing various components within the semiconductor package.

In some embodiments, the contact pins 123 may include pogo pins. Each pogo pin 123 includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and can be in contact with the bottom contactor at its bottom end. With these configurations, when the test socket is used for testing the semiconductor package, the top contactors of the pogo pins 123 can be in contact with the conductive pads 124 of the semiconductor component 120, and the bottom contactors can be in contact with the test pads 105 of the reference module. An external force can be applied onto the semiconductor package, thereby the semiconductor package may press the pogo pins 123 against the reference module to set up an electrical connection between the set of conductive pads 124 of the semiconductor component 120 and the set of test pads 105 of the reference module. As such, the pogo pins 123 may be movable vertically relative to the socket body 110 with the coil spring providing an elastic connection between the conductive pads 124 of the semiconductor component 120 and the test pads 105 of the reference module. In some embodiments, the apparatus may further include a socket lid 130 disposed above the socket body 110 and the semiconductor package. The socket lid 130 may be used for pushing the semiconductor package towards the test board 100, thereby providing the external force onto the semiconductor package and thus pressing the pogo pins 123 against the reference module. In some other embodiments, the contact pins 123 may include other types of elastic connectors, such as elastic conductive pillars.

Apart from the vertical alignment between the test pads 105 of the reference module and the conductive pads 124 of the semiconductor component 120, the at least one electronic component 121 included within the semiconductor package is also vertically aligned with the at least one reference electronic component 102. To be more specific, a projection of the electronic component(s) 121 on the test board 100 totally overlaps with a projection of the reference electronic component(s) 102 on the test board 100. In other words, the reference electronic component(s) 102 has a same composition, structure, functionality and layout as the at least one electronic component(s) 121 of the semiconductor package, such that the reference electronic component(s) 102 may be a duplicate of the electronic component(s) 121. In some other embodiments, the interior space defined by the upper seat 111 may have a different size and layout from the lower cavity 112 as long as each of the test pads 105 can be vertically aligned with one of the conductive pads 124, and the semiconductor component(s) 120 can be vertically aligned with the reference electronic component(s) 102.

This apparatus for testing a semiconductor package, for example, the semiconductor package, may offer multiple advantages when testing semiconductor packages. Firstly, since the contact pins 123 electrically couple the semiconductor component 120 to the at least one reference electronic component 102, the apparatus creates a complete electronic module including the semiconductor component 120 to be tested and the at least one reference electronic component 102 to mimic the semiconductor package including the semiconductor component 120 and the at least one electronic component 121. The testing process does not need to break the semiconductor package to get access to the semiconductor component 120 encapsulated within the mold cap 122, which brings convenience, improves test reliability and saves cost. Secondly, since the reference module may have a same size or layout as that of the semiconductor package, the test board 100 designed for the layout of the semiconductor package may still match the layout of the reference module when testing the semiconductor component 120, namely, the semiconductor package. For example, the connection means, e.g., traces, plugs or redistribution structures (RDSs) embedded within the test board 100 originally designed for providing signals for the semiconductor package may still provide optimal signals for the reference module when testing the semiconductor component 120 within the semiconductor package. As such, the test board 100 may be reused without additional adjustments, which improves the convenience of the testing process. Thirdly, since the at least one electronic component 121 has a same composition and layout as the at least one reference electronic component 102, the semiconductor package and the reference module may at least partially share a same fabrication process, and thus a fabrication cost can be strictly controlled in a mass production scenario.

In some other embodiments, the aforementioned apparatus may be slightly modified to test each of the electronic components encapsulated within the semiconductor package instead of the semiconductor component 120. For example, when testing the electronic component 121, the at least one reference electronic component of the reference module should have a same composition and layout as the semiconductor component 120 and electronic component(s) other than the electronic component 121 which are included within the semiconductor package. Also, the contact pins 123 should be arranged at suitable positions through the test socket to align with conductive pads 125 of the electronic component 121, which provides an electrical connection between the electronic component 121 and the at least one reference electronic component to mimic the semiconductor package. In this way, each of the components within the semiconductor package can be tested without removing the mold cap 122, and using the same test board 100, which is convenient and cost saving.

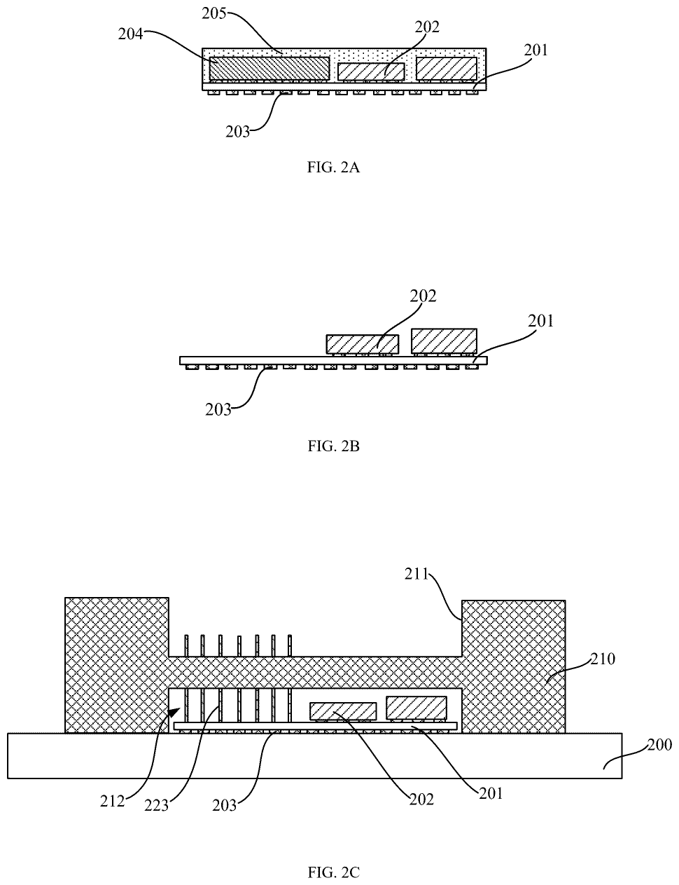

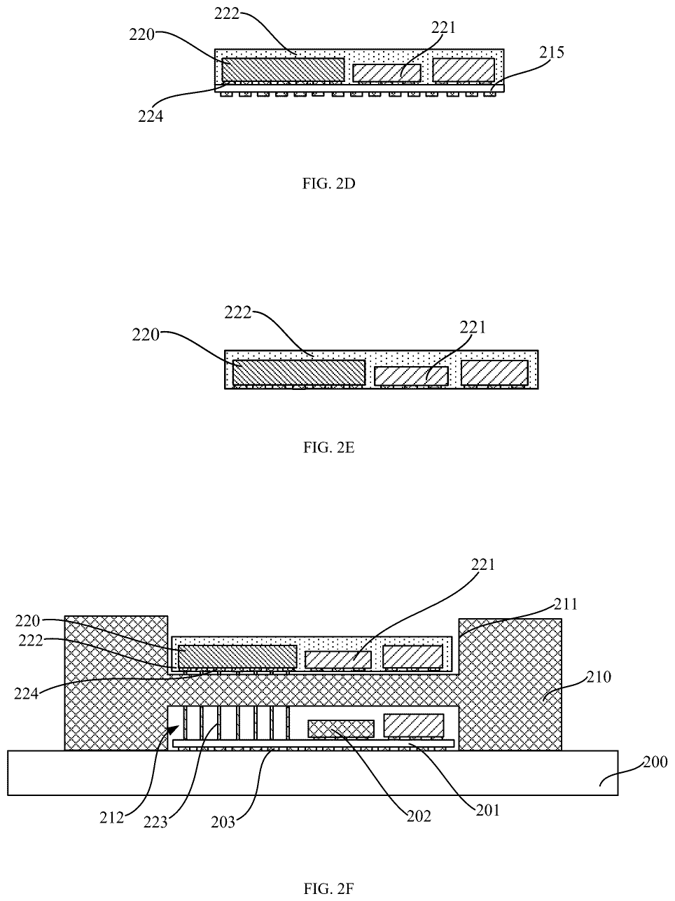

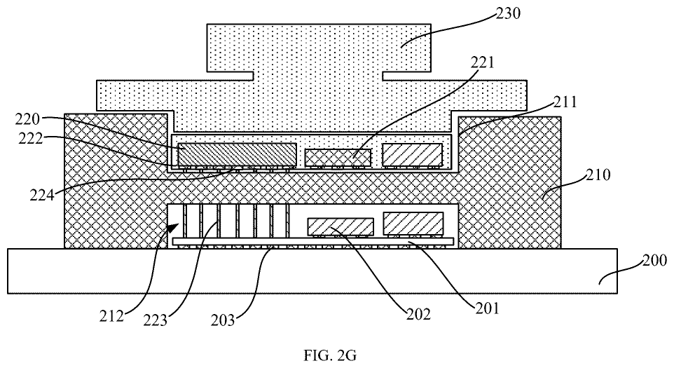

FIGS. 2A to 2G illustrate various steps of a method for testing a semiconductor package according to a second embodiment of the present application.

FIGS. 2A and 2B illustrate steps for forming a reference module in a process of testing a semiconductor package. As shown in FIG. 2A, a pre-mold package may be provided. The pre-molded package includes a base substrate 201, a first electronic component 204 and at least one reference electronic component 202 mounted on the base substrate 201, and a molding layer 205 encapsulating the first electronic component 204 and at least one reference electronic component 202. In particular, the first electronic component 204 is mounted on a set of test pads (not shown) on a front surface of the base substrate 201. It can be appreciated that the test pads may be exposed portions of interconnect wires formed within the base substrate 201. Furthermore, the base substrate 201 further includes additional conductive pads 203 on a back surface of the base substrate 201. The test pads and the additional conductive pads 203 may be electrically connected with each other through the interconnect wires formed within the base substrate 201, for example. Next, as shown in FIG. 2B, the molding layer 205 and the first electronic component 221 are removed from the base substrate 201 to expose the at least one reference electronic component 202 and the set of test pads on the base substrate 201, thereby forming the reference module.

Next, as shown in FIG. 2C, the reference module is placed on a test board 200 and electrically connected with connection means embedded within the socket board via the additional conductive pads 203. Next, a test socket having a socket body 210 and contact pins 223 vertically extending through the socket body 210 is placed on the test board 200. The socket body 210 has an upper seat 211 and a lower cavity 212 below the upper seat 211 to accommodate the reference module. The contact pins 223 are electrically coupled to the test pads on the base substrate 201, and extend between the lower cavity 212 and the upper seat 211.

Next, a semiconductor package to be tested is placed in the upper seat 211 of the test socket. FIGS. 2D and 2E illustrate steps for forming a semiconductor package before the semiconductor package is being tested. As shown in FIG. 2D, a semiconductor package is provided. The semiconductor package includes a package substrate 215, a semiconductor component 220 with a set of conductive pads 224 and at least one electronic component 221 mounted on the package substrate 215, and a mold cap 222 encapsulating the semiconductor component 220 and the at least one electronic component 221. The semiconductor package illustrated in FIG. 2D has a same composition and layout as the pre-molded package illustrated in FIG. 2A. As such, these two packages may be formed using a same fabrication process, and thus a fabrication cost can be strictly controlled in a mass production scenario. To be more specific, the at least one reference electronic component 202 has a same composition and layout as the at least one electronic component 221, and the test pads of the reference module also have a same layout as conductive pads 224 of the semiconductor component 220. Next, as shown in FIG. 2E, the package substrate 215 is removed to expose the set of conductive pads 224 from the mold cap 222, thereby forming the semiconductor package to be tested in a subsequent process.

Next, as shown in FIG. 2F, the semiconductor package is placed in the upper seat 211 of the test socket. The set of test pads of the reference module are vertically aligned with the set of conductive pads 224 of the semiconductor component 220 with the contact pins 223 vertically extending therebetween. Next, as shown in FIG. 2G, the semiconductor package is pushed towards the test board 200 by a socket lid 230 disposed above the socket body 210 and the semiconductor package to set up an electrical connection between the set of conductive pads 224 of the semiconductor component 220 and the set of test pads of the reference module. As such, the semiconductor component 220 can be tested by creating a complete testing electronic module including the semiconductor component 220 and the at least one reference electronic component 202, which mimics the semiconductor package including the semiconductor component 220 and the at least one electronic component 221 without damaging a structure of the semiconductor package.

The discussion herein includes numerous illustrative figures that show various portions of an apparatus for testing a semiconductor package and a method for testing a semiconductor package. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing a semiconductor package, wherein the semiconductor package comprises a semiconductor component, at least one electronic component and a mold cap encapsulating the semiconductor component and the at least one electronic component, the semiconductor component has a set of conductive pads exposed from the mold cap, and wherein the apparatus comprises:
a test board;
a reference module disposed on the test board, wherein the reference module comprises a base substrate with a set of test pads and at least one reference electronic component mounted on the base substrate, the at least one reference electronic component has a same composition and layout as the at least one electronic component of the semiconductor package; and
a test socket disposed on the test board, wherein the test socket comprises:
a socket body having an upper seat for seating the semiconductor package and a lower cavity below the upper seat and for accommodating the reference module, such that the set of test pads of the reference module are vertically aligned with the set of conductive pads of the semiconductor component when the semiconductor package is seated in the upper seat; and
contact pins vertically extending through the socket body between the upper seat and the lower cavity and movable vertically relative to the socket body, wherein when the semiconductor package is under test, the contact pins are pressed by the semiconductor package against the reference module to set up an electrical connection between the set of conductive pads of the semiconductor component and the set of test pads of the reference module.

2. The apparatus of claim 1, further comprising:
a socket lid disposed above the socket body and the semiconductor package, wherein the socket lid is configured for pushing the semiconductor package towards the test board.

3. The apparatus of claim 2, wherein the contact pins comprise pogo pins.

4. The apparatus of claim 1, wherein the test pads of the base substrate of the reference module are electrically coupled to the test board to allow for signaling between the semiconductor component and the test board.

5. A method for testing a semiconductor package, wherein the semiconductor package comprises a semiconductor component, at least one electronic component and a mold cap encapsulating the semiconductor component and the at least one electronic component, the semiconductor component has a set of conductive pads exposed from the mold cap; and wherein the method comprises:
providing a reference module disposed on the test board, wherein the reference module comprises a base substrate with a set of test pads and at least one reference electronic component mounted on the base substrate, the at least one reference electronic component has a same composition and layout as the at least one electronic component of the semiconductor package;
placing the reference module on a test board;
placing a test socket on the test board, wherein the test socket comprises a socket body having an upper seat and a lower cavity below the upper seat, and contact pins vertically extending through the socket body between the upper seat and the lower cavity and movable relative to the socket body, and wherein the reference module is accommodated within the lower cavity;
placing the semiconductor package in the upper seat of the test socket; and
pressing the semiconductor package toward the test board to press the contact pins against the reference module to set up an electrical connection between the set of conductive pads of the semiconductor component and the set of test pads of the reference module.

6. The method of claim 5, wherein pressing the semiconductor package toward the test board comprises:
pushing the semiconductor package towards the test board via a socket lid disposed above the socket body and the semiconductor package.

7. The method of claim 5, wherein the contact pins comprise pogo pins.

8. The method of claim 5, wherein the test pads of the base substrate of the reference module are electrically coupled to the test board to allow for signaling between the semiconductor component and the test board.
